(19) United States
(12) Patent Application Publication
(10) Pub. No.: US 2008/0057686 A1
(43) Pub. Date: Mar. 6, 2008

(54) CONTINUOUS DOPANT ADDITION

(76) Inventor: Hans L. Melgaard, North Oaks, MN (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(21) Appl. No.: 11/846,613

(22) Filed: Aug. 29, 2007

Related U.S. Application Data
(60) Provisional application No. 60/841,599, filed on Aug. 31, 2006.

(51) Int. Cl. H01L 21/38; C23C 16/00

(52) U.S. Cl. 438/565; 118/719; 257/E21.466

(57) ABSTRACT

A continuous dopant coater with improved control of the coating environment and methods and systems relating to the coater. Embodiments of the dopant coater may include a containment chamber and a coating chamber and the use of an inerting media to control the environment within and around the coater.

### CROSS REFERENCE TO RELATED APPLICATIONS

The present application claims priority from U.S. Patent Application No. 60/841,599 filed 31 Aug. 2006, the entire disclosure of which is incorporated herein by reference.

### TECHNICAL FIELD

The present invention relates to the production of silicon semiconductors, particularly photovoltaic cells. More particularly, the invention relates to continuous application to a silicon substrate of a dopant carried in a flammable solvent.

### BACKGROUND OF THE INVENTION

Photovoltaic cells are commonly formed using processes that include creating a P-N junction by diffusing dopants into a silicon-based material. The silicon-based material may be obtained pre-doped so that it is either P-type or N-type, and the opposite type dopant is then used in the junction formation process. Commonly, silicon doped with boron is used to form the P-type silicon a the phosphorous dopant can be used to create a layer of N-silicon on the top surface of the wafer.

One approach to the phosphorous diffusion process step is to stack silicon wafers on cassettes and place them in a quartz tube. Gaseous POCl₃ is introduced into the quartz tube. Wafers are exposed to this phosphorous source at a pre-determined temperature allowing the phosphorus to diffuse into the silicon. Other cell manufacturers use phosphoric acid as a phosphorous source, with the diffusion process carried out in a belt furnace. A common belt diffusion process applies a dilute solution of phosphoric acid and water sprayed, rolled, or spun on the wafer. The wafer is then placed on a belt and heated in a diffusion process heating step for a pre-determined time at a pre-determined temperature. Phosphorous diffusion into the silicon depends on the concentration of phosphorus on the surface of the wafer, the temperature at which the process takes place, and the dwell time at the elevated temperature.

Spray-on methods using dopants in aqueous carriers are limited by the fact that the solution tends to bead up on the silicon wafer due to the surface tension of the aqueous carrier. This can result in a non-uniform diffusion of phosphorus into the silicon chip. To prevent this, a surfactant may be added to the solution for the purposes of achieving wetting and providing a more uniform coating of the substrate by the dopant solution.

### BRIEF DESCRIPTION OF THE DRAWINGS

FIG. 1 is a unit operation schematic of a process in accordance with embodiments of the invention.

### DETAILED DESCRIPTION OF EMBODIMENTS OF THE INVENTION

A continuous dopant addition process is contemplated, utilizing low surface tension solvents to minimize concentration gradients of a dopant across a silicon substrate. Potential solvents for use in such a process include ethyl alcohol, isopropyl alcohol, N-propyl alcohol, ethyl acetate, acetone, and other organic and non-organic solvents that will occur to those skilled on the art. In one exemplary embodiment a phosphoric acid dopant is used in an ethyl alcohol carrier or solvent.

Embodiments of the invention include a dopant spray chamber in which the dopant mixture may be applied to the silicon substrate. The coating chamber may be configured to apply the dopant in any number of ways including, but not limited to, spraying the dopant on the substrate with ultrasonic nozzles, spraying the dopant on the substrate with inert atomizing nozzles, spraying the dopant on the substrate with misting nozzles directed at the wafers, or saturating the chamber with misting nozzles and condensing the dopant on the wafers. The particular fashion in which the dopant is applied to the wafers is not important and other approaches will occur to those skilled on the art upon reading this disclosure.

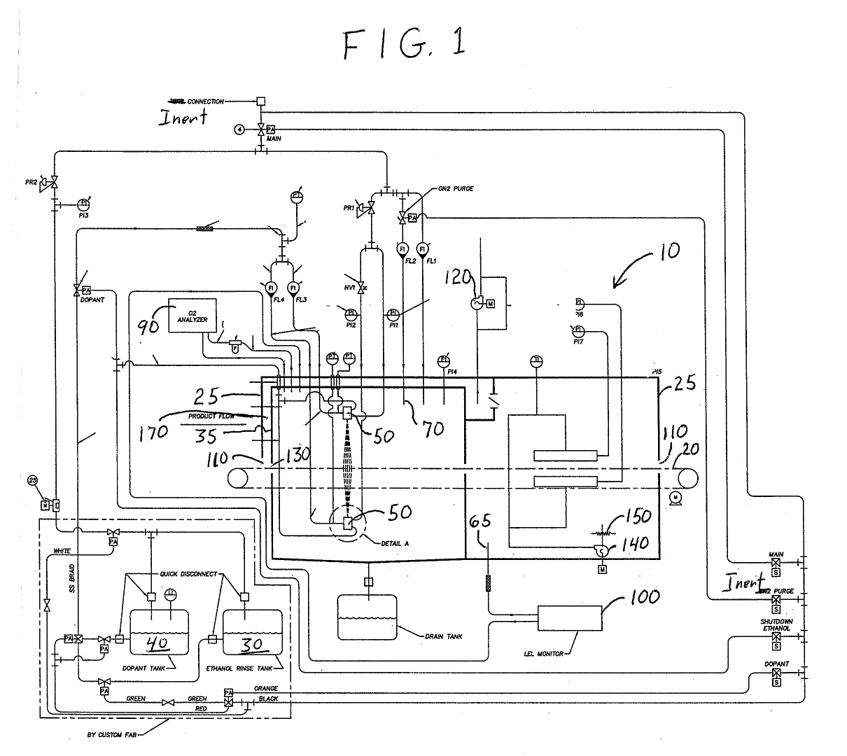

FIG. 1 is an schematic drawing of a coater in accordance with the invention. Coater 10 generally includes a conveyor 20, a containment chamber 25, a coating chamber 35 within the containment chamber, and one or more nozzles 50. The coater may also include one or more spargers 70 for introducing inert media to the coating chamber 35. In one embodiment, the nozzle 50 is a ultrasonic nozzle that applies a dopant solution supplied from a dopant tank 30 to silicon wafers that are conveyed through the chambers 25, 35 on the conveyor 20 in the direction of product flow indicated by arrow A. The wafers pass into and out of the containment chamber 25 through slots 110 that have a relatively tight tolerance to maintain a reasonable level of isolation of the chamber 25. The wafers pass into and out of the coating chamber 35 through slots 130 that also have a relatively tight tolerance.

Coaters in accordance with the invention may also include drying equipment. In the embodiment shown in FIG. 1, a heater blower 140 circulates heated gases that are heated by heating element 150. The gases are drawn from within the chamber, heated, and conveyed to distributor 160 located proximate the conveyor 20. The distributor may be a manifold with a plurality of openings or any other means of directing the heated gases to the wafers as they pass by on the conveyor 20. The blower 140 and heating element 150 are shown in FIG. 1 within the containment chamber 25, but they may be located outside of the chamber if circumstances require.

In some embodiments of the invention, the dopant that is applied to the silicon wafers is carried in a flammable solvent or carrier. Spraying such a dopant solution within the coating chamber 35 has the potential to create an explosive environment. A gaseous inerting agent, for example nitrogen, may be added to the coating chamber 35 through spargers 70 to reduce the level of oxygen and explosive solvents within the chamber 35 to an acceptable level. An inerting agent is a substance that is not readily reactive with other elements or compounds. Such spargers may be constructed of sintered metal to reduce the velocity at which the inerting agent is introduced. Sintered metal and other sparger designs that reduce the initial velocity of the inerting media reduce the potential for vortices to form within the chamber. Such vortices may be undesirable as they may cause localized low pressure zones within the chamber 35 that may cause unwanted air from outside the coating chamber to be drawn into the chamber potentially compromising the non-explosive nature of the coating chamber 35 environment.

The environment within the coating chamber 35 may be maintained at a slightly higher pressure than the surrounding environment. In some embodiments, the environment surrounding the coating chamber comprises the interior of a containment chamber 25. In the embodiment shown in FIG. 1, the coating chamber 35 be may be maintained at a slightly higher pressure than the containment chamber 25. The pressure within the coating chamber 35 may maintained by the addition of inerting agent as described herein. The excess inerting agent and/or volatile solvents and other gases may exit the coating chamber 35 primarily through the slots 130 at each end of the coating chamber 35. Alternatively the pressure within the chamber 35 could be controlled by a pressure control valve on a vent, by manual valves, or by an appropriately sized orifice plate that restricts outflow of the inerting medium from the coating chamber 35.

The pressure within the containment chamber 25 is maintained below the pressure of the external environment. A blower 120 may be used to remove excess gases and vapors from the chamber 25. The blower may be pressure controlled to provide for a negative pressure within the chamber 25 relative to the outside atmosphere to reduce the possibility that explosive or flammable vapors or gases from the coating chamber 35 leave the containment chamber 25 in an uncontrolled fashion. The negative pressure within the containment chamber draws ambient air into the containment chamber 25 through the slots 110. The airflow coming in through slot 110 may act as an air curtain to prevent gases exiting the coating chamber 35 to the containment chamber 25 through the slot 130 from exiting the containment chamber 25 through the slot 110. In some embodiments a containment duct 170 connects the main containment chamber 25 to the area outside of the entrance to the coating chamber 35 near the slot 130. This containment duct 170 helps ensure that gases flowing out of the slot 130 near the entrance to the coating chamber 35 are drawn into and contained within the containment chamber 25. In this way the potentially explosive or flammable vapors from the coating chamber 35 are diluted within the containment chamber and not allowed to be released to the ambient environment. The pressure and airflow control allows environment within the containment chamber 25 to be kept below an explosive threshold by the combination of ambient air inflow and inerting media from the coating chamber. The solvent vapor concentration in the containment chamber can be monitored and the mixture of solvent vapors, inerting media, and ambient air can be released from the containment chamber in a controlled fashion.

Controlling the environment within the coater and reducing the risk of explosion in the coating chamber is important for several reasons. The coater itself, as well as associated equipment used in the production of photovoltaic cells, includes many electrical components. Safety and regulatory considerations may require more expensive “explosion-proof” electrical components to be used in the area of the coater if the chamber were not maintained below an explosive threshold or if potentially explosive or flammable gases were to be released from the coater to the surrounding environment. Also, maintaining an inert atmosphere with a low impurity inerting agent such as nitrogen reduces the potential for contamination of the wafers by metals and other contaminants.

The production line for a photovoltaic cell includes several processing steps after the coating process. Processes in accordance with the invention use a diffusion furnace to create a doped layer on the surface of the wafer. These pieces of equipment also include several potential ignition sources, often in close proximity to the coater.

In another embodiment in accordance with the invention, the nozzles 50 are atomizing nozzles that are assisted by an inerting agent. Turning again to FIG. 1, an inerting agent is supplied through conduit 80 to nozzle 50 where it mixes with dopant solution. The gaseous inerting agent assists with the atomization of the dopant mixture as the dopant mixture is sprayed onto wafers that are transported past the nozzle 50 on the conveyor 20. In this embodiment it is possible that enough inerting agent may be supplied through nozzle 50 to adequately control the environment within the coating chamber 35 and maintain the required pressure in the coating chamber 35. Optionally, additional inerting agent may be supplied using spargers 70 as described above.

In another embodiment, the nozzles 50 are misting nozzles directed at the wafers. In this embodiment the dopant solution is sprayed on the wafers using misting nozzles that are well known in the art and the environment within the coating chamber 35 is maintained by adding inerting agent through spargers 70.

In yet another embodiment, dopant solution is introduced into the vapor space of the coating chamber 35 is using misting nozzles or other means. The environment may be controlled with inerting agent injected through spargers 70 as described above. The wafers are cooled prior to passing through the chamber and the dopant solution condenses on the relatively cold wafers. Such condensation processes are conducted under various conditions, but in one embodiment the wafers are cooled to approximately minus twenty degrees Fahrenheit (−20° F.). This cooling may be accomplished using the same inerting media used to control the environment within the chamber. For instance, if nitrogen is used as an inerting media, a liquid nitrogen stream could be vaporized to cool the wafers. The now-gaseous nitrogen could then be injected into the chamber 35 through spargers 70 to control the environment within the chamber.

Coaters in accordance with the invention may also include monitors to ensure that the environment within the coating chamber 35 and containment chamber 25 chamber are appropriately controlled. For example a vapor concentration monitor 100 can continuously measure the level of flammable components in the containment chamber 35 using sensors 60 and 65 to ensure that the inerting media is effectively purging the vaporized solvent and oxygen from the environment. Sensor 60 may be located in containment duct 170 to monitor the level of flammable components that are drawn into the duct from the region around slot 130. Additionally, or optionally, an oxygen analyzer 90 can continuously monitor the oxygen level within the coating chamber 35 and/or the containment chamber 25. In embodiments of the invention it is desirable to maintain the oxygen level within the coating chamber 35 below 10%, and more desirable to maintain the oxygen level below 5%, and even more desirable to maintain the oxygen level below 3%. It is desirable to maintain the vapor and oxygen concentration in the containment chamber below 50% of the lower explosive limit for the measured volatile components (50% LEL).

A purge tank 40 may be used to supply a liquid purge stream to clear the lines and nozzles of the coater. The purge liquid may be the same carrier used in the dopant solution or any material appropriate to ensure that the equipment is cleared of residual dopant when necessary for cleaning or maintenance.

While preferred embodiments of the present invention have been described, it should be understood that various changes, adaptations and modifications may be made therein without departing from the spirit of the invention and the scope of the appended claims.

What is claimed is:

1. An apparatus comprising:
a. a coating chamber having a dopant applicator for applying dopant to material to be treated;
b. an inerting media source that maintains a low oxygen environment within the coating chamber;
c. a containment chamber that generally encompasses the coating chamber to prevent material from the coating chamber from entering the ambient environment; and
d. a conveyor that passes through the coating chamber and the containment chamber configured to convey material to be treated through the coating chamber and the containment chamber.

2. The apparatus of claim 1, further comprising a blower that maintains the containment chamber at a negative pressure relative to the surrounding environment.

3. The apparatus of claim 2, wherein the containment chamber is maintained below 50% of the LEL and at a negative pressure relative to the surrounding environment.

4. The apparatus of claim 1, further comprising a dryer for drying the material to be treated as it passes through the containment chamber.

5. The apparatus of claim 4, wherein the heater comprises a blower that recycles gases from the containment chamber to a manifold proximate the conveyor and a heating element that heats the recycled gas stream.

6. A method of treating a material to be treated comprising the steps of:
a. placing the material to be treated on a conveyor;
b. conveying the material to be treated into a coating chamber, the coating chamber being located within a containment chamber;
c. applying a dopant solution to the material to be treated, the dopant solution comprising a low surface tension solvent;
d. introducing an inert medium into the coating chamber to reduce the potential for undesirable reactions.

7. The method of claim 6, wherein the low surface tension solvent is selected from a group consisting of ethyl alcohol, isopropyl alcohol, N-propyl alcohol, ethyl acetate, and acetone.

8. The method of claim 6, wherein the low surface tension solvent is flammable and the introduction of the inert medium into the coating chamber reduces the potential for combustion or explosion.

9. The method of claim 6, wherein the step of applying the dopant solution comprises spraying the solution with at least one atomizing spray nozzle.

10. The method of claim 6, wherein the step of applying the dopant solution comprises introducing a high concentration of dopant solution vapor into the coating chamber and cooling the material to be treated so that dopant solution condenses on the material to be treated.

11. The method of claim 6, further comprising the step of drying the material to be treated.

12. The method of claim 11, wherein the drying step comprises heating gas in the containment chamber and blowing the gas to a manifold proximate the material to be treated as it is conveyed through the containment chamber.

13. The method of claim 6, further comprising the step of maintaining the containment chamber at a negative pressure relative to the surrounding environment.
